(19) United States
(12) Patent Application Publication
(10) Pub. No.: US 2008/0048731 A1
(43) Pub. Date: Feb. 28, 2008

(54) COMPARATOR AND METHOD FOR OPERATING THEREOF

(75) Inventor: Kuan-Hsun Huang, Yunlin County (TW)

Correspondence Address: J C PATENTS, INC., 4 VENTURE, SUITE 250, IRVINE, CA, 92618, US

(73) Assignee: FARADAY TECHNOLOGY CORP., Hsinchu (TW)

(21) Appl. No.: 11/467,429

(22) Filed: Aug. 25, 2006

(51) Int. Cl. H03K 5/22

(52) U.S. Cl. 327/65

(57) ABSTRACT

A comparator including an amplifier unit, a latch unit, and a switch unit is provided. The amplifier unit receives and gains an input signal pair respectively and then outputs an output signal pair. The latch unit is coupled to the amplifier unit. During a tracking period, the latch unit is not powered, and during a latching period, the latch unit is powered to latch the output signal pair and then output a logical signal pair accordingly. The switch unit is coupled between the amplifier unit and the latch unit. During the tracking period, the switch unit transfers the output signal pair to the latch unit, and during the latch period, the switch unit separates the amplifier unit from the latch unit, and thereby reducing the influences to the comparator caused by the kick back noise and the offset error.

### BACKGROUND OF THE INVENTION

1. Field of Invention

The present invention relates to a comparator, and more particularly, to a comparator that can reduce the kick back noise and the offset error.

2. Description of Related Art

As for a comparator in the conventional art, the logical signal pair of the comparator outputs logic states (i.e., logic 1 and logic 0) corresponding to the logic state for signals of the input signal pair according to the differences in signals of the input signal pair. In other words, if the input signal A of the comparator is larger than the input signal B, the input signal A is output as logic 1, and the input signal B is output as logic 0 after being processed by the comparator. On the contrary, if the input signal A is less than the input signal B, the input signal A is output as logic 0, and the input signal B is output as logic 1. For example, “A 10-bit 200-MS/S CMOS parallel pipeline A/D converter” published on IEEE Journal of Solid-State Circuit (JSSC), Page 1048-1055, in June 2001, and “A 69-mW 10-bit 80-MSample/s Pipelined CMOS ADC” published on IEEE JSSC, Page 2031-2039, in December 2003, and the like are all conventional comparators.

FIG. 1 is a block diagram of a conventional comparator. FIG. 2 is a control timing diagram of a comparator 100 in FIG. 1. Referring to both FIG. 1 and FIG. 2, the comparator 100 comprises an amplifier unit 101, a switch unit 103 and a latch unit 105. The amplifier unit 101 gains a received input signal pair INP, INN, respectively, and then provides an output signal pair INP′, INN′. The switch unit 103 is coupled between the output signal pair INP′, INN′ of the amplifier unit 101, and controlled by a clocking signal CK1. Thus, during the tracking period T, the switch unit 103 provides a reset voltage Vreset, such that the level of the output signal pair INP′, INN′ is reset as the reset voltage Vreset (e.g., system voltage VDD). The latch unit 105 is directly coupled to the amplifier unit 101, and controlled by a clocking signal CK2, such that after the signals of the output signal pair for the amplifier unit 101 are latched during the latching period L, a logical signal pair S1, S2 is output.

Generally, the comparator 100 in the conventional art often outputs the logic states represented by the signals of the input signal pair incorrectly due to the influence by the kick back noise and the offset error. It can be seen from the comparator 100 of FIG. 1 that, since the amplifier unit 101 is directly connected to the latch unit 105, the kick back noise generated during the operation process of the latch unit 105 bolts back to the amplifier unit 101, resulting in errors when processing the input signal pair by the amplifier unit 101, and thereby the latch unit 105 processes the signals of an incorrect output signal pair, and so, finally, the output of the comparator 100 is incorrect. In addition, since parasitic capacitances of the output signal pair INP′, INN′ provided by the amplifier unit 101 are different, errors possibly occur when the latch unit 105 processes the signals for the input signal pair, thereby resulting in an output error of the comparator 100.

### SUMMARY OF THE INVENTION

Accordingly, the present invention provides a comparator and a method for operating the comparator, which can reduce the influences to the comparator caused by the kick back noise and the offset error, and thus the logical signal pair output by the comparator is more accurate.

The comparator provided in the present invention comprises an amplifier unit and a latch unit. The amplifier unit is used to receive and gain an input signal pair, and then output an output signal pair. The latch unit is coupled to the amplifier unit, and the latch unit is not powered during the tracking period, and during the latching period, it is powered to latch the output signal pair and output a logical signal pair accordingly.

In an embodiment of the present invention, the comparator further comprises a switch unit coupled between the amplifier unit and the latch unit. The switch unit is used to transfer the output signal pair of the amplifier unit to the latch unit during the tracking period, and separate the amplifier unit from the latch unit during the latching period.

From another point of view, the present invention provides a comparator, which comprises an amplifier unit, a switch unit and a latch unit. The amplifier unit is used to receive and gain an input signal pair, and then output an output signal pair. The switch unit, coupled to the amplifier unit, is used to transfer the output signal pair of the amplifier unit to the latch unit during a tracking period, and separate the amplifier unit from the latch unit during the latching period. The latch unit is coupled to the switch unit, and controlled by the second clocking signal, and the latch unit is used to receive the output signal pair during the tracking period, and then latch the output signal pair and output a logical signal pair accordingly during the latching period.

From another point of view, the present invention provides a method for operating the comparator, which includes the following steps: receiving and gaining an input signal pair first, and then outputting an output signal pair; then, storing the output signal pair during the tracking period; finally, latching the output signal pair during the latching period, outputting a logical signal pair accordingly, and separating the output signal pair from the logical signal pair.

As for the comparator of the present invention, during the tracking period, the output signal pair of the amplifier unit is stored in the parasitic capacitor of the latch unit, and the source end of the latch unit is floating, such that when the latch unit is powered during the latching period, it can latch the output signal pair of the amplifier unit accurately, and then output the correct logic levels without being influenced by the offset error. In addition, since the amplifier unit is separated from the latch unit during the latching period, the influences to the comparator (even the front-stage circuit of the comparator) due to the kick back noise can be aovided, and thereby the logical signal pair output by the comparator is more accurate.

In order to make the aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram of a comparator in the conventional art.

FIG. 2 is a control timing diagram of the comparator in FIG. 1.

FIG. 3 shows a comparator according to a preferred embodiment of the present invention.

FIG. 4 is a control timing diagram of the comparator of FIG. 3 according to this embodiment.

FIG. 5 shows a comparator according to another embodiment of the present invention.

FIG. 6 is a control timing diagram of the comparator of FIG. 5 according to this embodiment.

FIG. 7 shows a flow chart of a method for operating the comparator according to a preferred embodiment of the present invention.

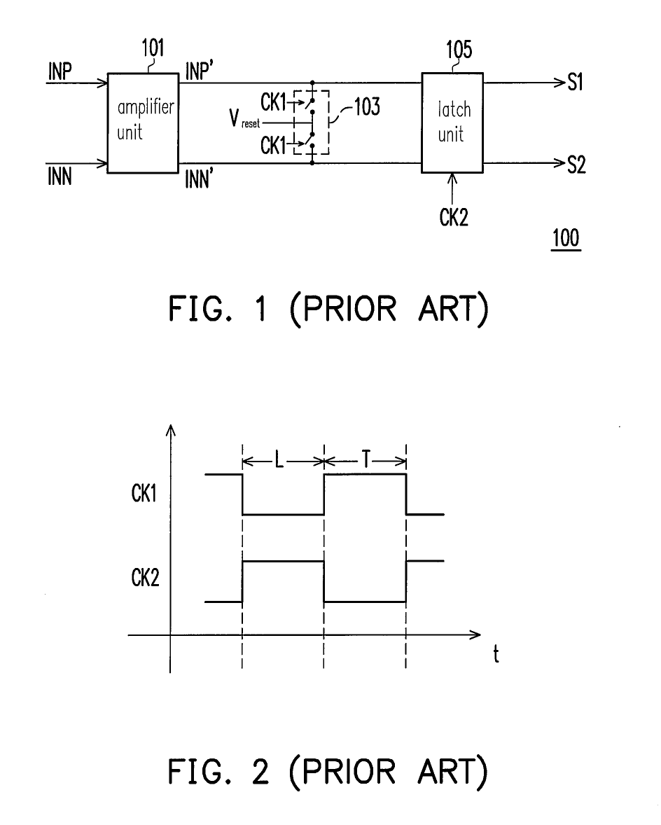

### DESCRIPTION OF EMBODIMENTS

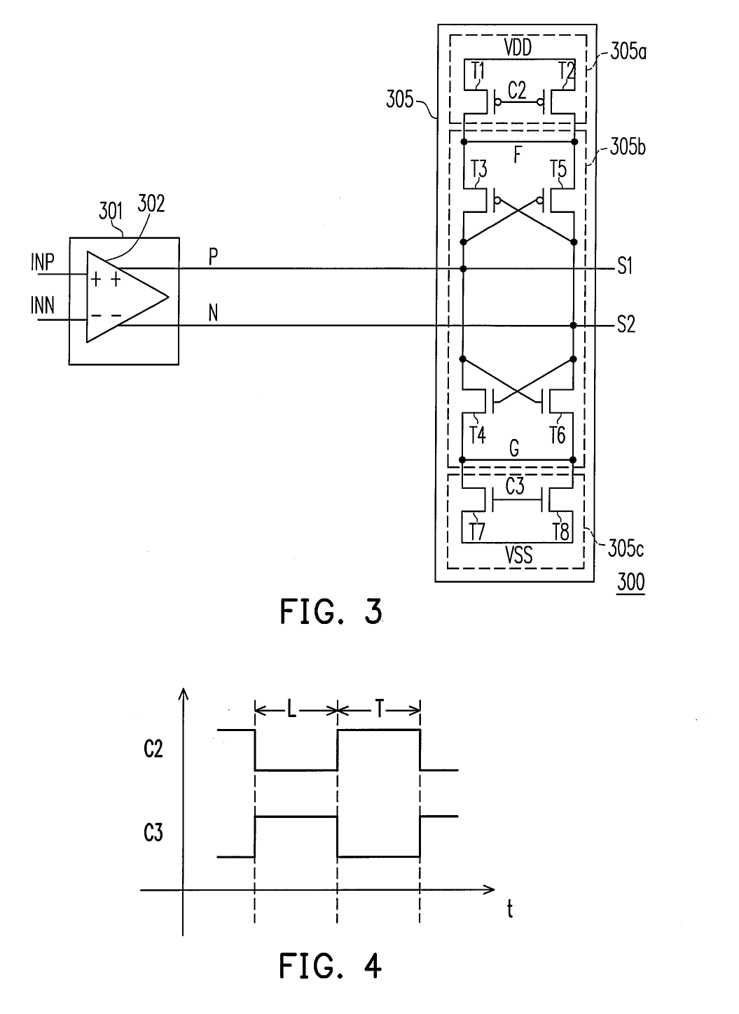

FIG. 3 shows a comparator 300 according to a preferred embodiment of the present invention. FIG. 4 is a control timing diagram of the comparator 300 according to this embodiment. Referring to both FIG. 3 and FIG. 4, the comparator 300 comprises an amplifier unit 301 and a latch unit 305. The amplifier unit 301 is used to receive and gain an input signal pair (including a first input signal INP and a second input signal INN), and then output an output signal pair (including a first output signal P and a second output signal N). The latch unit 305 is coupled to the amplifier unit 301. During the tracking period T, the latch unit 305 is controlled not to provide power to the internal circuits. During the latching period L, the latch unit 305 is controlled to provide power to the internal circuits. Thus, the latch unit 305 latches the output signal pair, and outputs a logical signal pair (including a first logic signal S1 and a second logic signal S2) accordingly.

In this embodiment, the amplifier unit 301 comprises a pre-amplifier 302. The pre-amplifier 302 has a first input end, a second input end, a first output end, and a second output end, wherein the first and second input ends are used to respectively receive the input signals INP and INN, and the first and second output ends are used to respectively output the output signals P and N.

The latch unit 305 comprises a positive feedback unit 305b, a first power switch unit 305a and a second power switch unit 305c. The positive feedback unit 305b stores the output signal pair of the amplifier unit 301 into the internal parasitic capacitor during the tracking period, and outputs a corresponding logical signal pair according to the stored output signal pair during the latching period, by supplying or not supplying power from the first source end F and the second source end G. The first power switch unit 305a separates the positive feedback unit 305b from the first voltage source VDD (as system voltage herein) during the tracking period T, and electrically connects the positive feedback unit 305b to the first voltage source VDD during the latching period L. The second power switch unit 305c separates the positive feedback unit 305b from the second voltage source VSS (as ground voltage herein) during the tracking period T, and electrically connects the positive feedback unit 305b to the second voltage source VSS during the latching period L.

In this embodiment, the positive feedback unit 305b comprises a third transistor T3, a fourth transistor T4, a fifth transistor T5 and a sixth transistor T6, wherein the sources of the transistor T3 and transistor T5 are coupled to each other, and act as the first source end F of the positive feedback unit 305b. The sources of the transistor T4 and transistor T6 are coupled to each other, and act as the second source end G of the positive feedback unit 305b. The gates of the transistor T3 (P-type transistor herein) receive the second output signal N, and are respectively coupled to the drain of the transistor T5 (P-type transistor herein) and the drain of the transistor T6 (N-type transistor herein). The gates of the transistor T4 (N-type transistor herein) also receive the second output signal N, and are respectively coupled to the drains of transistors T5 and T6. The gates of the transistor T5 receive the first output signal P, and are respectively coupled to the drains of the transistors T3 and T4. The gates of the transistor T6 also receive the first output signal P, and are coupled to the drains of the transistors T3 and T4. The drains of the transistors T3 and T5 respectively output the first logic signal S1 and the second logic signal S2.

In this embodiment, the first power switch unit 305a includes a first transistor T1 and a second transistor T2. The drains and sources of the transistors T1 and T2 (both are P-type transistor herein) are respectively coupled to the first source end F of the positive feedback unit 305b and the first voltage source VDD, and the gates of the transistors T1 and T2 receive the second clocking signal C2. The second power switch unit 305c comprises a seven transistor T7 and an eighth transistor T8. The drain and source of the transistors T7 and T8 (both are N-type transistor herein) are respectively coupled to the second source end G of the positive feedback unit 305b and the second voltage source VSS, and the gates of the transistors T7 and T8 receive a third clocking signal C3.

For example, when the first input signal INP and the second input signal INN received by the amplifier unit 301 are 10 mV and 1 mV, the first output signal P and the second output signal N of the amplifier unit 301 are 1V and 0.1V after being amplified (for e.g., 100 times) by the gain value of the amplifier unit 301 itself. That is to say, under ideal circumstances, the amplifier unit 301 can enlarge the voltage difference of 9 mV (i.e., 10 mV−1 mV) of the original input signal pair to a difference of 0.9V (i.e., 1V−0.1V) so that the latching process performed by the latch unit 305 to the output signal pair will be more accurate.

Then, if the comparator 300 is at the tracking period T, the transistor T1, the transistor T2, the transistor T7 and the transistor T8 of the latch unit 305 are turned off. Thus, the source ends F and G of the positive feedback unit 305b are both floating. In addition, since there is no complete discharging path, the first output signal P and the second output signal N are completely stored into the parasitic capacitor of the positive feedback unit 305b by the amplifier unit 301. If the comparator 300 is at the latching period L, the transistor T1, the transistor T2, the transistor T7 and the transistor T8 of the latch unit 305 are turned on. Thus, the positive feedback unit 305b positively feeds back the first output signal P and the second output signal N stored in the internal parasitic capacitor, such that the first output signal P is converted to the first logic signal S1 (i.e., logic 1 or logic 0) and then output, and the second output logic signal N is converted to the second logic signal S2 (with a logic state different from that of the first logic signal) and then output.

Compared with the conventional art, the comparator 300 is not required to reset the first output signal P and the second output signal N to be a reset voltage Vreset during the tracking period T. In this embodiment, when the comparator 300 is at the tracking period T, the first output signal P and the second output signal N are both stored in the internal parasitic capacitor of the latch unit 305, and the latch unit 305 is floating. When the comparator 300 is at the latching period L, the logical signal pair must be correctly output by the comparator 300, no matter there are great or few influences to the amplifier unit 301 and the latch unit 305 caused by the offset error.

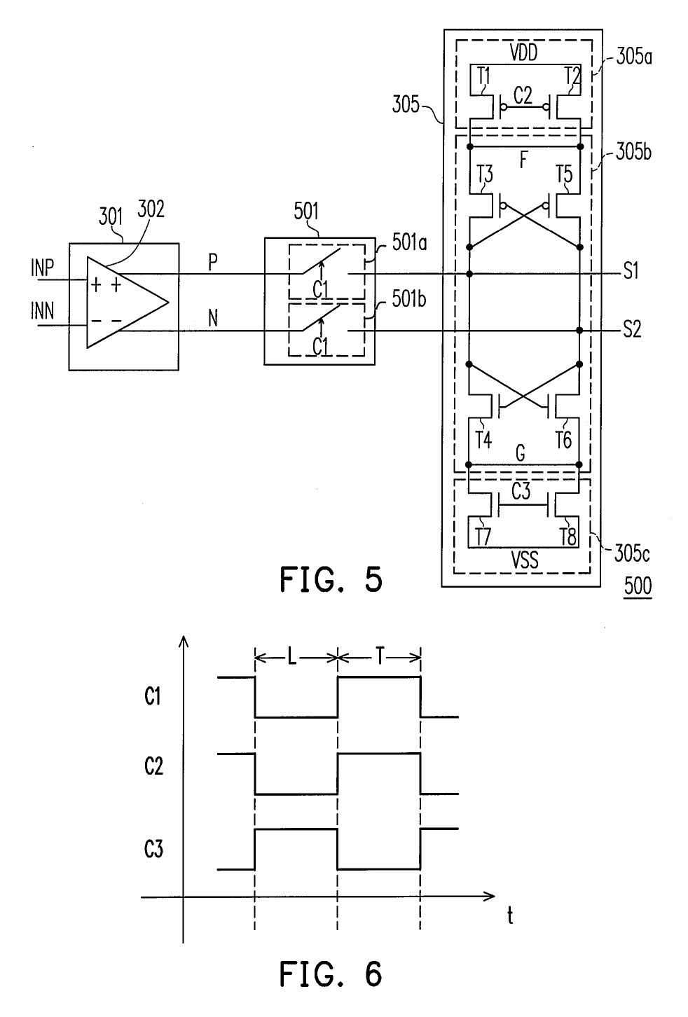

FIG. 5 shows a comparator 500 according to another embodiment of the present invention. In this embodiment, the main difference in the circuit structure between the comparator 500 and the comparator 300 in FIG. 3 lies in that, the comparator 500 further includes a switch unit 501 coupled between the amplifier unit 301 and the latch unit 305, and the switch unit 501 transfers the output signal pair of the amplifier unit 301 to the latch unit 305 during the tracking period T, and separates the amplifier unit 301 from the latch unit 305 during the latching period L.

FIG. 6 is a control timing diagram of the comparator 500 according to this embodiment. Referring to both FIG. 5 and FIG. 6, in this embodiment, the switch unit 501 comprises a first switch 501a and a second switch 501b. The first switch 501a is coupled between the amplifier unit 301 and the latch unit 305, and used to determine whether to transfer one signal (the first output signal P, herein) of the output signal pair to the latch unit 305. The second switch 501b is also coupled between the amplifier unit 301 and the latch unit 305, and used to determine whether to transfer the other signal (the second output signal N, herein) of the output signal pair to the latch unit 305. In addition, the first switch 501a and the second switch 501b are both controlled by the first clocking signal C1 to be turned on during the tracking period T and turned off during the latching period L.

In this embodiment, if the comparator 500 is at the latching period L, the switch unit 501 is turned off, the amplifier unit 301 is separated from the latch unit 305, therefore, the kick back noise is not conducted back to the amplifier unit 301 via the latch unit 305, and does not influence the processing for the first input signal INP and the second input signal INN performed by the amplifier unit 301, and thereby the output of the comparator 300 is more accurate. If the comparator 500 is at the tracking period T, the operation principle is similar to that of the comparator 300, and thus the details will not be described herein any more. According to the spirit of the present invention, the latch unit 305 of the comparator 500 is not limited to any latch of a certain architecture.

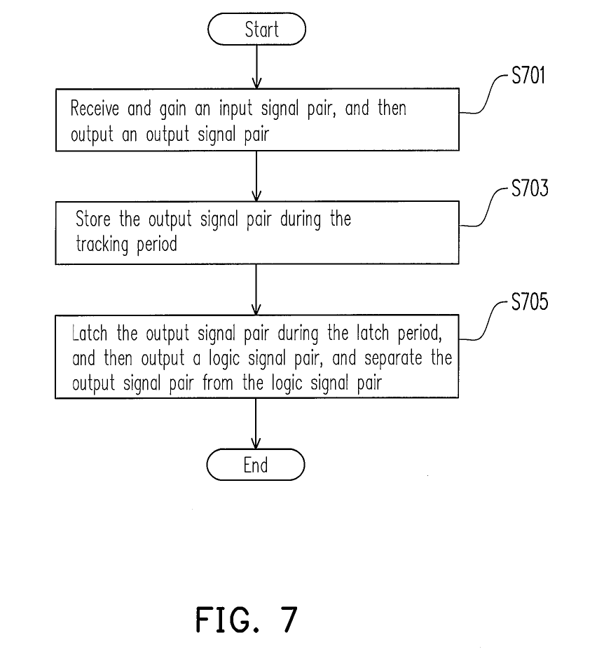

FIG. 7 is a flow chart of a method for operating a comparator according to a preferred embodiment of the present invention. First, as described in Step S701 of the present invention, an input signal pair is received and gained, and then an output signal pair is output. Then, as described in Step S703 of the present invention, the output signal pair is stored during the tracking period. Finally, as described in Step S705 of the present invention, the output signal pair is latched during the latching period, and then a logical signal pair is output, and the output signal pair and the logical signal pair are separated from each other.

In this embodiment, the input signal pair includes a first input signal and a second input signal; the output signal pair includes a first output signal and a second output signal; and the logical signal pair includes a first logic signal and a second logic signal.

In the above embodiment, the input signal pair are analog signals.

In summary, the present invention provides a comparator and a method for operating the comparator. According to the spirit of the present invention, the present invention has the following advantages.

1. The influence to the amplifier unit caused by the kick back noise is reduced.

2. The influence to the comparator due to the offset error caused by the amplifier unit and the latch unit is reduced.

3. The logical signal pair output by the comparator is more accurate.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A comparator, comprising:
an amplifier unit, for receiving and gaining an input signal pair, and outputting an output signal pair; and
a latch unit, coupled to the amplifier unit, wherein the latch unit is not powered during a tracking period, the latch unit is powered during a latching period to latch the output signal pair, and outputting a logical signal pair accordingly.

2. The comparator as claimed in claim 1 further comprising a switch unit, wherein the switch unit is coupled between the amplifier unit and the latch unit, the switch unit is used to transfer the output signal pair of the amplifier unit to the latch unit during the tracking period, and separate the amplifier unit from the latch unit during the latching period.

3. The comparator as claimed in claim 2, wherein the switch unit comprises:
a first switch, coupled between the amplifier unit and the latch unit, and used for determining whether to transfer one signal of the output signal pair to the latch unit; and
a second switch, coupled between the amplifier unit and the latch unit, and used for determining whether to transfer the other signal of the output signal pair to the latch unit.

4. The comparator as claimed in claim 3, wherein under the control of a first clocking signal, the first and second switches are turned on during the tracking period, and turned off during the latching period.

5. The comparator as claimed in claim 1, wherein the amplifier unit comprises a pre-amplifier having a first input end and a second input end for respectively receiving the corresponding signals of the input signal pair, and a first output end and a second output end for respectively outputting the corresponding signals of the output signal pair.

6. The comparator as claimed in claim 1, wherein the latch unit comprises:
a positive feedback unit, powered from a first source end and a second source end and coupled to the amplifier unit, wherein the positive feedback unit stores the output signal pair therein, and outputting the logical signal pair accordingly;
a first power switch unit, coupled between the first source end of the positive feedback unit and a first voltage source, used for separating the positive feedback unit from the first voltage source during the tracking period, and electrically connecting the positive feedback unit to the first voltage source during the latching period; and
a second power switch unit, coupled between the second source end of the positive feedback unit and a second voltage source, used for separating the positive feedback unit from the second voltage source during the tracking period, and electrically connecting the positive feedback unit to the second voltage source during the latching period.

7. The comparator as claimed in claim 6, wherein the first voltage source is used to supply a system voltage, and the second voltage source is used to supply a ground voltage.

8. The comparator as claimed in claim 1, wherein the input signal pair is analog signals.

9. A comparator, comprising:
an amplifier unit, for receiving and gaining an input signal pair, and outputting an output signal pair;
a switch unit, coupled to the amplifier unit, used for transferring the output signal pair of the amplifier unit to the latch unit during a tracking period, and separating the amplifier unit from the latch unit during a latching period; and
a latch unit, coupled to the switch unit, controlled by a second clocking signal and used for receiving the output signal pair during the tracking period, latching the output signal pair during the latching period, and outputting a logical signal pair accordingly.

10. The comparator as claimed in claim 9, wherein the amplifier unit comprises a pre-amplifier having a first input end and a second input end for respectively receiving the corresponding signals of the input signal pair, and a first output end and a second output end for respectively outputting the corresponding signals of the output signal pair.

11. The comparator as claimed in claim 9, wherein the switch unit comprises:
a first switch, coupled between the amplifier unit and the latch unit, used for determining whether to transfer one signal of the output signal pair to the latch unit; and
a second switch, coupled between the amplifier unit and the latch unit, used for determining whether to transfer the other signal of the output signal pair to the latch unit.

12. The comparator as claimed in claim 11, wherein under the control of a first clocking signal, the first and second switches are turned on during the tracking period, and turned off during the latching period.

13. The comparator as claimed in claim 9, wherein the input signal pair are analog signals.

14. A method for operating a comparator, comprising:
receiving and gaining an input signal pair, and then outputting an output signal pair;
storing the output signal pair during a tracking period; and
latching the output signal pair during a latching period, outputting a logical signal pair, and separating the output signal pair from the logical signal pair.

15. The method for operating a comparator as claimed in claim 14, wherein the input signal pair includes a first input signal and a second input signal.

16. The method for operating a comparator as claimed in claim 14, wherein the output signal pair includes a first output signal and a second output signal.

17. The method for operating a comparator as claimed in claim 14, wherein the logical signal pair includes a first logic signal and a second logic signal.

18. The method for operating a comparator as claimed in claim 14, wherein the input signal pair are analog signals.
